(19) United States
(12) Patent Application Publication
(10) Pub. No.: US 2006/0134881 A1
(43) Pub. Date: Jun. 22, 2006

(54) Method of forming trench isolation device capable of reducing corner recess

(76) Inventors: Been-Jon Woo, Shanghai (CN); Hao Fang, Shanghai (CN); Mon-Chin Tsai, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/013,415

(22) Filed: Dec. 17, 2004

(51) Int. Cl. H01L 21/762

(52) U.S. Cl. 438/424; 438/435; 438/426

(57) ABSTRACT

A method of forming a trench isolation device capable of reducing corner recess comprising forming a pad oxide layer and a silicon nitride mask layer on a semiconductor base, and forming a trench by etching. Next, a liner oxide layer is formed on the semiconductor base and on the surface of the shallow trench. Then, the silicon nitride mask layer will be etched to reveal the corner. Finally, a layer of oxide is formed on the base to fill up the trench so that the trench isolation device can be completed. The present invention is designed to solve the corner recess problem, reduce generation of kick effect, and enhance the device characteristics and electrical quality.

### FIELD OF THE INVENTION

The present invention relates to a method of forming a shallow trench isolation device and, more particularly, to a method of forming a trench isolation device that is capable of reducing the corner recess.

### BACKGROUND OF THE INVENTION

A conventional isolation structure that employs local oxidation of silicon is more likely to result in a bird's beak effect since when the device feature size becomes smaller, its integration gets higher. For this reason, the isolation structure of a semiconductor device commonly employs the structure of a shallow trench isolation as an isolation area between semiconductor devices.

A trench device plays a significant role in semiconductor devices. Take a shallow trench isolation device as an example, the recess phenomenon occurrs in its corner portion which will cause quality deterioration of the semiconductor device. For instance, a kick effect can be generated to degrade the quality. The reason for the generation of the recess phenomenon in the corner of shallow trench isolation device is that the oxide layer of the corner structure may be substantially lost during processing. To illustrate this situation, first, a trench 12 is formed in a semiconductor base 10, as shown in FIG. 1. Then, a liner oxide layer 14 is formed on the surface of the trench 12, and an oxide 16 is used for filling in the trench to form a shallow trench isolation device. During a conventional processing procedure, the liner oxide layer 14 and oxide 16 may generate a denting phenomenon after completing the formation of trench device; therefore, a recess phenomenon may also occur in the corner structure 18 of the trench isolation device. As a result, the electrical quality of the device may be degraded, and in turn a kick effect may be produced in the device.

In viewing of the above-mentioned problems, the invention provides a method of forming a trench isolation device capable of reducing the corner recess so that the conventional drawbacks caused by the corner-structure recess can be resolved.

### SUMMARY OF THE INVENTION

The present invention provides a method of forming a trench isolation device capable of reducing the corner recess, which extends the liner oxide layer and the filled-in oxide for covering the whole trench and corner structure of the trench, so that the trench corner can be better covered to reduce the recess phenomenon.

The present invention also provides a method of forming a trench isolation device capable of reducing the corner recess, which effectively reduces the occurrence of the kick effect, so that the device characteristics and electrical quality of the device can be enhanced.

To achieve the aforementioned objects, firstly, the method of the present invention forms a pad oxide layer and a silicon nitride mask layer on a semiconductor base. Next, a patterned resist layer is used as a mask to etch the silicon nitride mask layer, the pad oxide layer, and the semiconductor base so as to form a trench. The patterned mask layer is removed and a liner oxide layer is formed on the semiconductor base and the surface of shallow trench. The silicon nitride mask layer is etched for a pullback so as to reveal its corner structure or alternatively, the silicon nitride mask layer can be etched first before forming the liner oxide layer. In such case, after the pullback is done and the corner structure is exposed, a deposition is performed to form the liner oxide layer. Finally, an oxide layer is formed on the semiconductor base to fill up the trench, and then the unwanted oxide layer, liner oxide layer, silicon nitride mask layer, and pad oxide layer on the surface of the semiconductor base are removed, and thus the formation of trench isolation device is completed.

The objects, technical contents, and features of the present invention will be better understood through descriptions of the following embodiments with reference to the drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional diagram illustrating a conventional trench isolation device structure;

FIGS. 2(a)˜2(f) are sectional diagrams illustrating steps of manufacturing a trench isolation device according to an embodiment of the present invention; and

FIGS. 3(a)˜3(f) are sectional diagrams illustrating steps of manufacturing a trench isolation device according to another embodiment of the present invention.

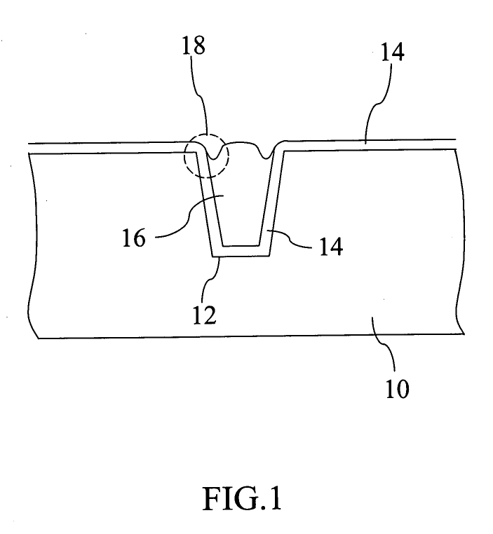

### DETAILED DESCRIPTION OF THE PREFERRED EMBODIMENTS

As mentioned above, the recess phenomenon generated in a conventional shallow trench isolation device can cause a kick effect and affect the device characteristics. As a result, the yield rate and electrical quality of the device can be lowered. On the other hand, the present invention applies a pullback function generated by the silicon nitride mask layer to prevent the conventional drawbacks. Therefore, the recess problem and kick effect can be avoided, and the device characteristics can be maintained.

It should be noted that the schematic sectional diagrams shown in the embodiments are drawn without taking into consideration that the semiconductor structure should be in proportion to a real one. That is, if a semiconductor structure in the diagram is enlarged, it is enlarged for clearer illustrations but not for showing the exact size of the semiconductor. In other words, in real manufacturing process, the three dimensions of the semiconductor, including its length, width, and depth, should be more seriously considered.

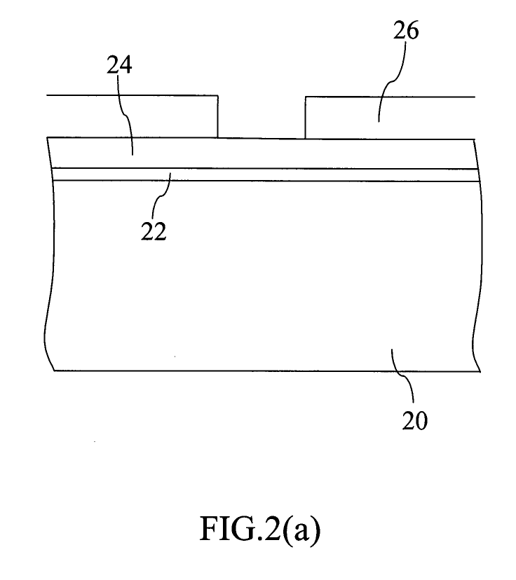

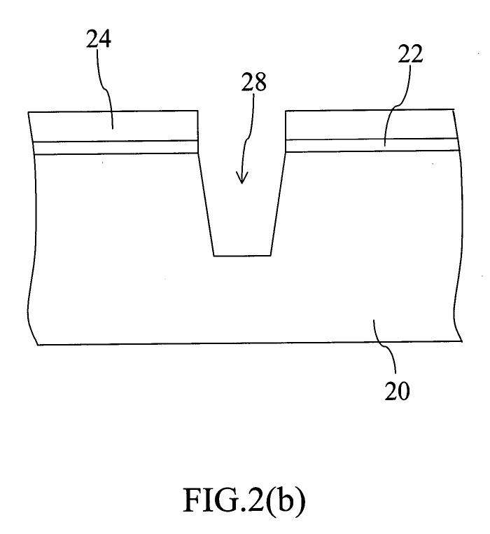

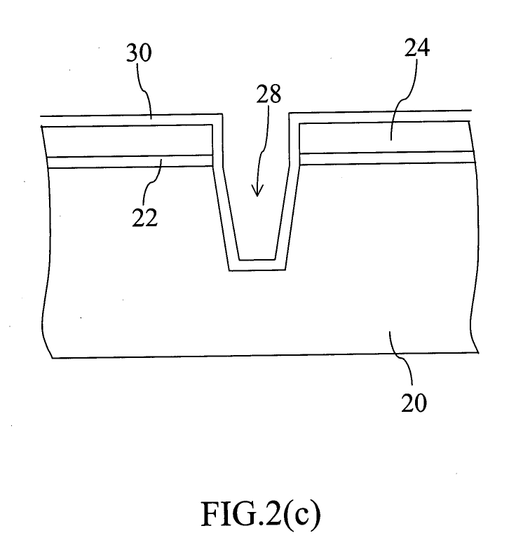

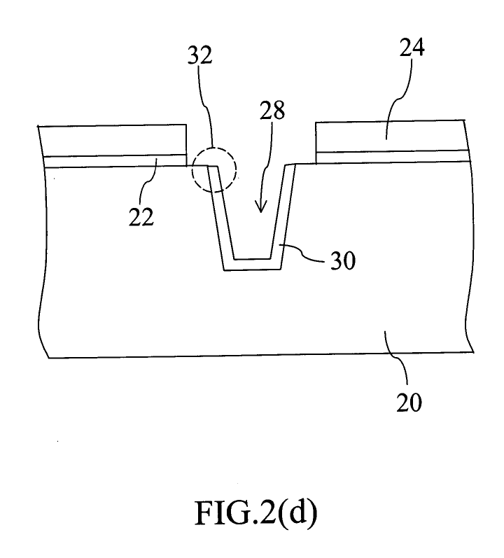

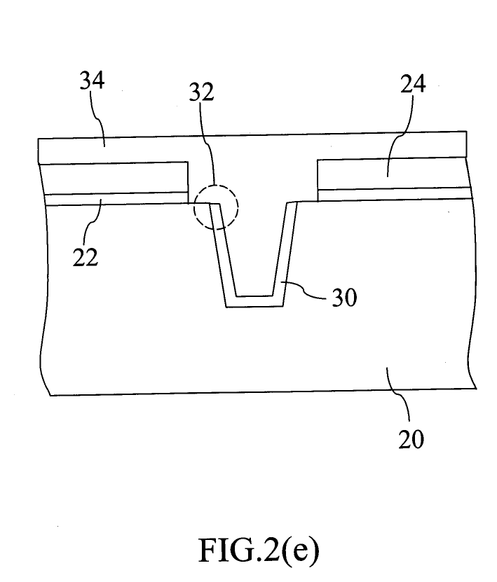

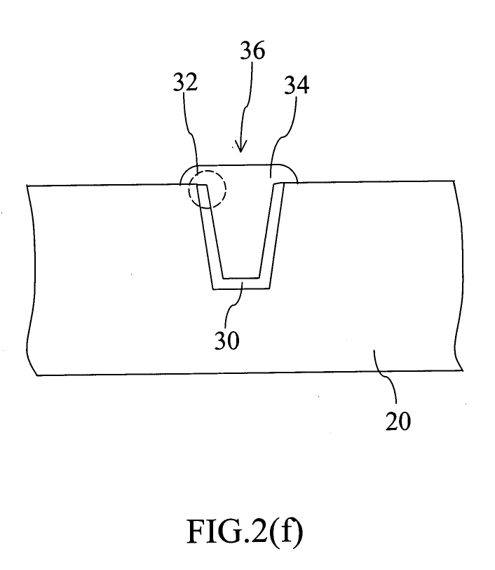

FIGS. 2(a)˜2(f) are sectional diagrams illustrating steps of manufacturing a trench isolation device according to one embodiment of the present invention. As shown in these Figures, the method disclosed in the present invention includes the steps described as follows. Firstly, as shown in FIG. 2(a), a semiconductor base 20 is provided, and a pad oxide layer 22 is formed on the surface of the semiconductor base 20 through chemical vapor deposition. The pad oxide layer 22 is normally composed of silicon dioxide. Next, a silicon nitride mask layer 24 is formed on the pad oxide layer 22. In an embodiment, the semiconductor structure employs the semiconductor base 20 that contains the pad oxide layer 22; alternatively, the semiconductor structure can be silicon on insulator or inter-layer dielectric.

Secondly, a patterned resist layer 26 is formed on the surface of the silicon nitride mask layer 24 of the semiconductor base 20. Then, the patterned resist layer 26 is used as a mask, and an etch technique is applied to remove the silicon nitride mask layer 24, pad oxide layer 22, and semiconductor base 20, which are not covering the patterned resist layer 26. After the removal of the exposed silicon nitride mask layer 24, pad oxide layer 22, and semiconductor base 20, a trench 28 can be formed on the semiconductor base 20, as shown in FIG. 2(b). When the trench 28 has been formed through an etching technique, the patterned resist layer 26 can be removed.

Thirdly, referring to FIG. 2(c), a liner oxide layer 30, which is used for insulating protection, can be formed by means of deposition on the semiconductor base 20 and the surface of the trench 28. Then, isotropic etching is applied to the silicon nitride mask layer 24 for etch processing until the silicon nitride mask layer 24 is pulled back for 500 Å to expose the corner structure 32, as shown in FIG. 2(d).

Fourthly, referring to FIG. 2(e), a layer of oxide 34 is formed on the semiconductor base 20 through high-density plasma deposition. The oxide 34 is used to fill up the trench 28 and to cover the surface of liner oxide layer 30. Alternatively, the oxide 34 can be undoped silicate glass.

Finally, the technique of either chemical mechanical polishing or plasma etching can be employed to remove the unwanted oxide 34, liner oxide layer 30, and silicon nitride mask layer 24 on the surface of the semiconductor base 20, so as to form a trench isolation device 36, as shown in FIG. 2(f). Afterwards, subsequent semiconductor processing should be performed on the semiconductor base 20 for further processing. In short, because the present invention utilizes the oxide 34 for extending and covering the whole trench 28 and its corner structure 32, the trench 28 can then be better covered, and in turn the recess phenomenon can be reduced as well as the kick effect can be prevented.

Also, in addition to the above-mentioned processing flow, there is another embodiment specifying different processing procedures. Firstly, a pad oxide layer 22, a silicon nitride mask layer 24, and a trench 28 are all formed on a semiconductor base 20. As for the formation process of these three components, it has been described in the aforementioned embodiment along with FIGS. 2(a)˜2(f). Therefore, it will not be reiterated here.

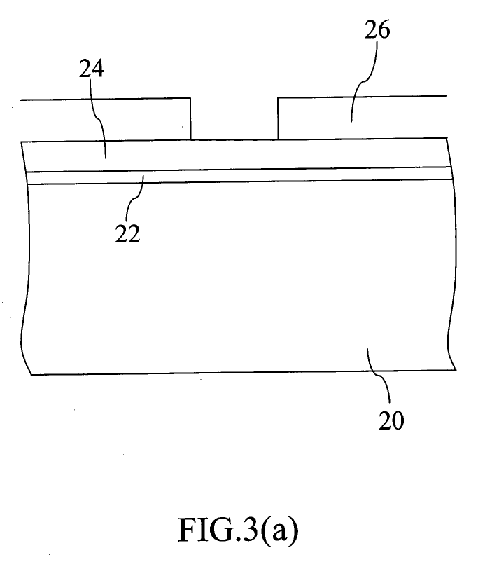

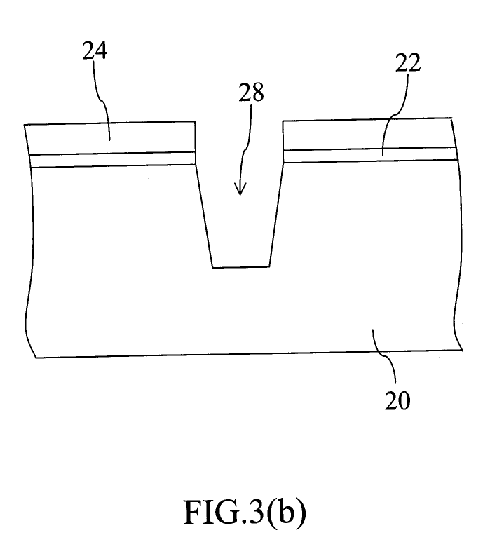

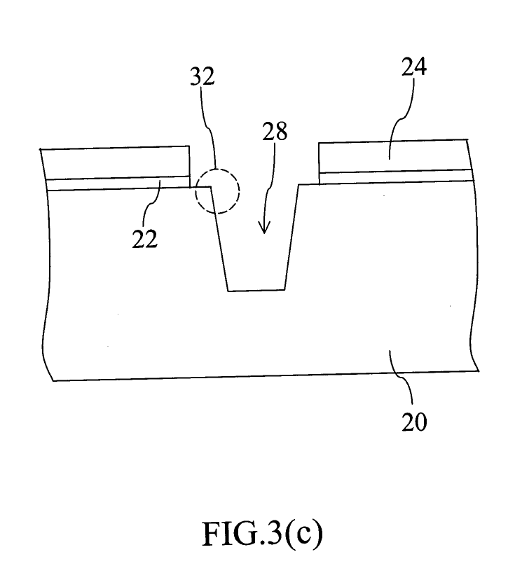

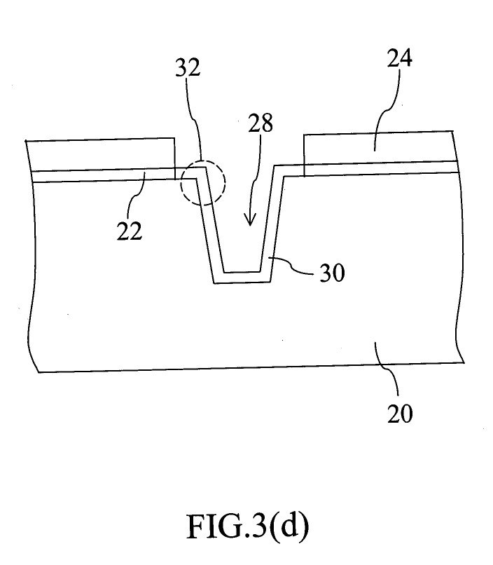

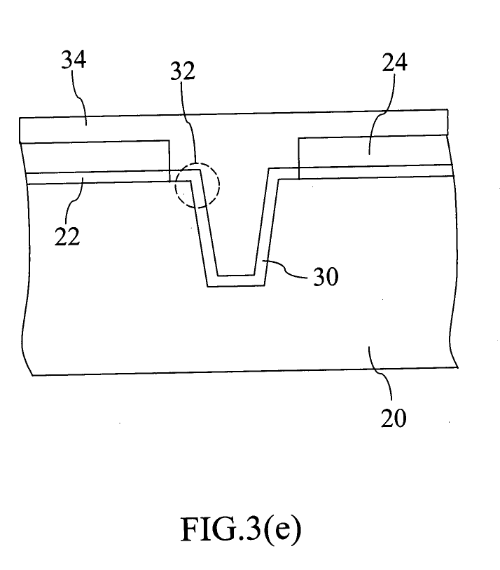

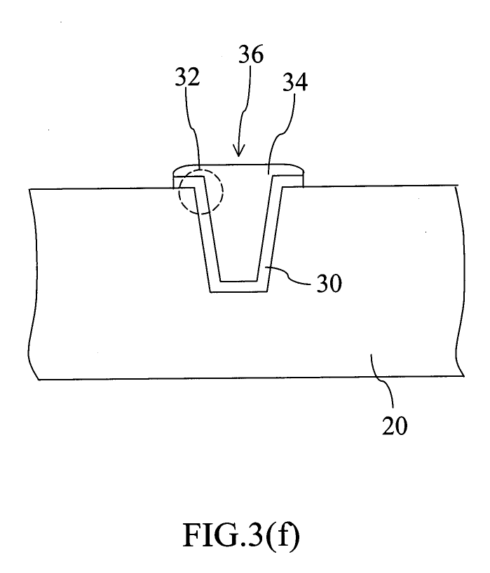

Secondly, an etch technique with high selectivity rate over the silicon nitride mask layer 24 is applied to the silicon nitride mask layer 24 for etching until the silicon nitride mask layer 24 has been pulled back for 500 Å, as shown in FIG. 3(c), in order to reveal the corner structure 32. Then, high-temperature thermal oxidation is performed, as shown in FIG. 3(d), and a liner oxide layer 30 is formed on the semiconductor base 20 and on the surface of the trench 28 through deposition technique for isolating protection.

Thirdly, referring to FIG. 3(e), a layer of oxide 34 is formed on the semiconductor base 20 by means of high-density plasma deposition. The oxide 34 is to fill up the trench 28 and to cover the surface of liner oxide layer 30. Alternatively, the oxide 34 can be undoped silicate glass.

Finally, the technique of either chemical mechanical polishing or plasma etching is employed to remove the unwanted oxide 34, liner oxide layer 30, and silicon nitride mask layer 24 on the surface of the semiconductor base 20, so as to form the trench isolation device 36, as shown in FIG. 3(f). Because the present invention utilizes the liner oxide 30 and oxide 34 for extending and covering the whole trench 28 and its corner structure 32, the trench 28 can then be better covered, and the recess phenomenon can be reduced as well as the kick effect can be prevented.

In conclusion, the present invention extends the liner oxide layer and the filled-in oxide for covering the whole trench and its corner structure in order that the trench corner can be better covered. Consequently, the recess phenomenon and the kick effect can both be reduced, thereby enhancing device characteristics and electrical quality of the device.

The embodiments above are only intended to illustrate the present invention; they do not, however, to limit the present invention to the specific embodiments. Accordingly, various modifications and changes may be made by those skilled in the art without departing from the spirit and scope of the present invention as described in the following claims.

What is claimed is:

1. A method of forming a trench isolation device capable of reducing corner recess, comprising:
providing a semiconductor structure, and forming a silicon nitride mask layer thereon;
forming a patterned mask layer on the surface of the semiconductor structure, and using the patterned mask layer as a mask for etching the silicon nitride mask layer and a portion of the semiconductor structure so as to form a trench;
removing the patterned mask layer;
forming a liner oxide layer on the semiconductor structure for covering the surface of the trench;
etching the silicon nitride mask layer for a pullback in order to reveal the corner structure of the trench;
forming a layer of oxide on the semiconductor structure so that the oxide can fill up the trench and cover the corner structure; and
removing the unwanted oxide and silicon nitride mask layer on the surface of the semiconductor structure so as to form the trench isolation device.

2. The method of forming a trench isolation device capable of reducing corner recess as claimed in claim 1, wherein the semiconductor structure is composed of a semiconductor base and a pad oxide layer that is formed on the surface of the semiconductor base, so that the trench can be formed in the base of the semiconductor.

3. The method of forming a trench isolation device capable of reducing corner recess as claimed in claim 2, wherein the pad oxide layer is composed of silicon dioxide.

4. The method of forming a trench isolation device capable of reducing corner recess as claimed in claim 1, wherein the semiconductor structure is a structure of silicon on insulator, which allows the trench to be formed in the silicon on insulator.

5. The method of forming a trench isolation device capable of reducing corner recess as claimed in claim 1, wherein the semiconductor structure is a structure of inter-layer dielectric, which allows the trench to be formed in the inter-layer dielectric.

6. The method of forming a trench isolation device capable of reducing corner recess as claimed in claim 1, wherein the mask layer is a patterned resist layer.

7. The method of forming a trench isolation device capable of reducing corner recess as claimed in claim 1, wherein the liner oxide layer is formed by means of high-temperature thermal oxidation.

8. The method of forming a trench isolation device capable of reducing corner recess as claimed in claim 1, wherein the oxide is formed by high density plasma deposition.

9. The method of forming a trench isolation device capable of reducing corner recess as claimed in claim 1, wherein the oxide comprises undoped silicate glass.

10. The method of forming a trench isolation device capable of reducing corner recess as claimed in claim 1, wherein in the procedure of etching the silicon nitride mask layer, a pullback etching is applied to the silicon nitride mask layer by employing isotropic etching.

11. The method of forming a trench isolation device capable of reducing corner recess as claimed in claim 1, wherein after the trench isolation device is formed, subsequent semiconductor processing is performed on the semiconductor structure for further semiconductor device manufacturing.

12. A method of forming a trench isolation device capable of reducing corner recess, comprising:
providing a semiconductor structure, and forming a silicon nitride mask layer thereon;
forming a patterned mask layer on the surface of the semiconductor structure, and using the patterned mask layer as a mask to etch the silicon nitride mask layer and a portion of the semiconductor structure so as to form a trench;
removing the patterned mask layer;
etching the silicon nitride mask layer for a pullback in order to reveal a corner structure of the trench;
forming a liner oxide layer on the semiconductor structure for covering the surface of the trench; and
forming a layer of oxide on the semiconductor structure so that the oxide can fill up the trench and cover the corner structure; and
removing unwanted oxide and the silicon nitride mask layer on the surface of the semiconductor structure so as to form the trench isolation device.

13. The method of forming a trench isolation device capable of reducing corner recess as claimed in claim 12, wherein the semiconductor structure is composed of a semiconductor base and a pad oxide layer that is formed on the surface of the semiconductor base, so that the trench can be formed in the base of the semiconductor.

14. The method of forming a trench isolation device capable of reducing corner recess as claimed in claim 13, wherein the pad oxide layer is composed of silicon dioxide.

15. The method of forming a trench isolation device capable of reducing corner recess as claimed in claim 12, wherein the semiconductor structure is a structure of silicon on insulator, which allows the trench to be formed in the silicon on insulator.

16. The method of forming a trench isolation device capable of reducing corner recess as claimed in claim 12, wherein the semiconductor structure is a structure of inter-layer dielectric, which allows the trench to be formed in the inter-layer dielectric.

17. The method of forming a trench isolation device capable of reducing corner recess as claimed in claim 12, wherein the mask layer is a patterned resist layer.

18. The method of forming a trench isolation device capable of reducing corner recess as claimed in claim 12, wherein the liner oxide layer is formed by means of high-temperature thermal oxidation.

19. The method of forming a trench isolation device capable of reducing corner recess as claimed in claim 12, wherein the liner oxide layer covers the corner structure.

20. The method of forming a trench isolation device capable of reducing corner recess as claimed in claim 12, wherein the method of forming the oxide is by applying high density plasma deposition.

21. The method of forming a trench isolation device capable of reducing corner recess as claimed in claim 12, wherein the oxide comprises undoped silicate glass.

22. The method of forming a trench isolation device capable of reducing corner recess as claimed in claim 12, wherein in the procedure of etching the silicon nitride mask layer, a pullback etching is applied to the silicon nitride mask layer by employing isotropic etching.

23. The method of forming a trench isolation device capable of reducing corner recess as claimed in claim 12, wherein after the trench isolation device is formed, subsequent semiconductor processing is performed on the semiconductor structure for further semiconductor device manufacturing.
